(19) United States
(12) Patent Application Publication
(10) Pub. No.: US 2009/0085637 A1
(43) Pub. Date: Apr. 2, 2009

(54) Apparatus effecting interface between differing signal levels

(76) Inventors: Steven K. Hsu, Lake Oswego, OR (US); Himanshu Kaul, Portland, OR (US); Ram K. Krishnamurthy, Portland, OR (US)

Correspondence Address: LAW OFFICE OF DONALD D. MONDUL;c/o INTELLEVATE, P.O. BOX 52050, MINNEAPOLIS, MN, 55402, US

(21) Appl. No.: 11/906,166

(22) Filed: Sep. 28, 2007

(51) Int. Cl. H03L 5/00

(52) U.S. Cl. 327/333

(57) ABSTRACT

An apparatus includes: a signal receiving unit receiving an input signal and presenting a first signal varying within a first signal range; a signal treating unit coupled with the signal receiving unit, receiving the first signal and presenting a second signal varying within a second signal range; and an output unit coupled with the signal treating unit. The signal treating unit and the output unit receive a control signal. The signal treating unit responds to the control signal to provide the second signal to the output unit when the control signal has a first value and to not provide the second signal to the output unit when the control signal has a second value. The output unit permits presentation of an output signal when the control signal has the first value and establishes the output signal at a predetermined value when the control signal has the second value.

### BACKGROUND

Some electronic systems, such as by way of example and not by way of limitation multi-core systems, multi-cache systems and system-on-a-chip systems, may have multiple power domains or other occurrences of interfacing sub-systems having differing power needs or other differing signal needs. It may be beneficial to effect an interface arrangement between such disparate domains to translate signal levels between the domains while operating. It may also be beneficial to provide isolation between the domains to guard against effects of floating nodes upon the domains.

### BRIEF DESCRIPTION OF THE DRAWINGS

The subject matter regarded as embodiments of the invention may be particularly pointed out and distinctly claimed in the concluding portion of the specification. Embodiments of the invention, however, both as to organization and method of operation, together with objects, features, and advantages thereof, may best be understood by reference to the following detailed description when read with the accompanying drawings in which:

FIG. 1 illustrates a first embodiment of an apparatus effecting interface between differing signal levels.

FIG. 2 illustrates a second embodiment of an apparatus effecting interface between differing signal levels.

FIG. 3 illustrates a first embodiment of an apparatus effecting interface between differing signal levels employing NMOS isolation.

FIG. 4 illustrates a first embodiment of an apparatus effecting interface between differing signal levels employing PMOS isolation.

FIG. 5 illustrates a second embodiment of an apparatus effecting interface between differing signal levels employing NMOS isolation.

FIG. 6 illustrates a second embodiment of an apparatus effecting interface between differing signal levels employing PMOS isolation.

FIG. 7 illustrates a first embodiment of an apparatus effecting interface between differing signal levels employing logic level isolation.

FIG. 8 illustrates a second embodiment of an apparatus effecting interface between differing signal levels employing logic level isolation.

FIG. 9 illustrates a first embodiment of an output unit appropriate for use with an apparatus effecting interface between differing signal levels.

FIG. 10 illustrates a second embodiment of an output unit appropriate for use with an apparatus effecting interface between differing signal levels.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of embodiments of the invention. However, it will be understood by those skilled in the art that embodiments of the present invention may be practiced without these specific details. In other instances, well-known methods, procedures, components and circuits have not been described in detail so as not to obscure embodiments of the present invention.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” my be used to indicated that two or more elements are in either direct or indirect (with other intervening elements between them) physical or electrical contact with each other, and/or that the two or more elements co-operate or interact with each other (e.g. as in a cause an effect relationship).

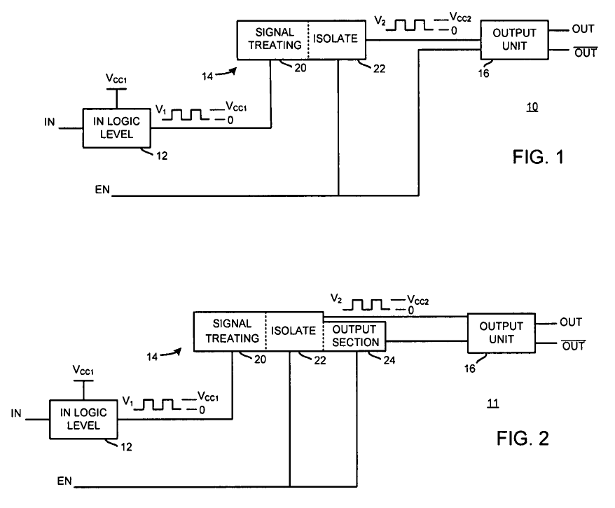

FIG. 1 illustrates a first embodiment of an apparatus effecting interface between differing signal levels. In FIG. 1, an apparatus 10 may include a signal receiving unit 12 coupled with a signal treating unit 14. An output unit 16 may be coupled with signal treating unit 14.

Signal receiving unit 12 may receive an input signal IN and may receive a first reference signal V_{CC1}. Signal receiving unit 12 may present a first signal V₁ to signal treating unit 14. First signal V₁ may vary between a first low logic level 0 and a first high logic level V_{CC1}.

Signal treating unit 14 may include a signal treating section 20 and an isolating section 22. Signal treating section 20 may receive first signal V₁ and present a second signal V₂. Second signal V₂ may vary between a second low logic level 0 and a second high logic level V_{CC2}. Isolating section 22 may receive a control signal EN (signal EN may also be referred to as an enabling signal). Isolating section 22 may respond to control signal EN to permit presenting second signal V₂ when control signal EN may be in a first state or when control signal EN may have a first value. Isolating section 22 may respond to control signal EN to not permit presenting second signal V₂ when control signal EN may be in a second state or when control signal EN may have a second value.

Output unit 16 may receive second signal V₂ from signal treating unit 14 depending upon restrictions that may be placed upon permitting presenting of second signal V₂ by isolating section 22. Output unit 16 may also receive control signal EN. Output unit 16 may permit presentation of an output signal OUT when control signal EN may have the first value. Output signal OUT may be related with second signal V₂. Output unit 16 may establish output signal OUT at a predetermined value when control signal EN may have the second value. Output unit 16 may also present an inverse output signal O̅U̅T̅. Inverse output signal O̅U̅T̅ may be related with output signal OUT in a predetermined way, such as by way of example and not by way of limitation, inverse output signal O̅U̅T̅ being equal with a negative expression of the value |OUT| of signal OUT.

It may be preferred that apparatus 10 is embodied in a single integrated circuit.

FIG. 2 illustrates a second embodiment of an apparatus effecting interface between differing signal levels. In FIG. 2, an apparatus 11 may include a signal receiving unit 12 coupled with a signal treating unit 14. An output unit 16 may be coupled with signal treating unit 14. Apparatus 11 may be substantially similar with apparatus 10 (FIG. 1) in several aspects, so in order to avoid prolixity only differences between apparatus 11 and apparatus 10 will be described here.

In apparatus 11, signal treating unit further 14 may include an output section 24. Output section 24 may perform at least a portion of functions described in connection with output unit 16 in apparatus 10. Output section 24 (instead of output unit 16) may receive control signal EN. Output section 24 may respond to value of control signal EN to affect operation of output unit 16 in presenting output signal OUT substantially as described in connection with apparatus 10 (FIG. 1). Thus, output section 24 may be viewed as substantially sharing functionality with output unit 16, which functionality may be carried out solely by output unit 16 in apparatus 10. Providing a separate output section 24 in signal treating unit 14 may permit a designer to employ a variety of component sizes and capacities in order to effect a more balanced operation of apparatus 11 as compared with apparatus 10. By way of example and not by way of limitation, providing output section 24 in signal treating unit 14 may permit apparatus 11 to provide improved gain for higher power levels with larger loads and better delay characteristics as compared with apparatus 10. Providing output section 24 may also permit reducing size of one or more of signal treating section 20 and isolating section 22 to facilitate addressing design aspects of apparatus 11 such as delay, power and area design aspects.

It may be preferred that apparatus 11 is embodied in a single integrated circuit.

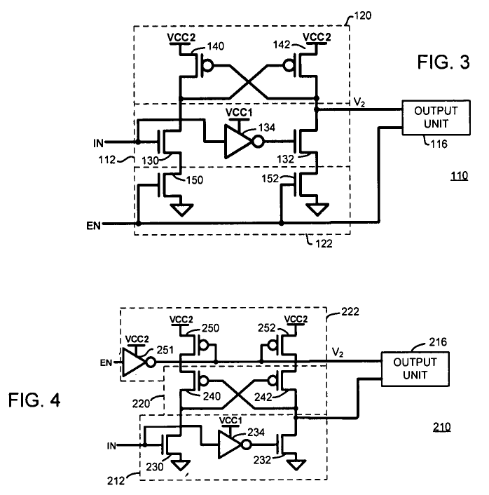

FIG. 3 illustrates a first embodiment of an apparatus effecting interface between differing signal levels employing NMOS isolation. In FIG. 3, an apparatus 110 may be an implementation of apparatus 10 (FIG. 1) including a signal receiving unit 112, a signal treating section 120, an isolating section 122 and an output unit 116.

Signal receiving unit 112 may include NMOS (N-channel Metal Oxide Semiconductor) transistor devices 130, 132 and an inverter device 134. Signal treating section 120 may include PMOS (P-channel Metal Oxide Semiconductor) transistor devices 140, 142. Isolating section 122 may include NMOS transistor devices 150, 152. Each of transistor devices 130, 132, 140, 142, 150, 152 may have a gate, a drain and a source. Such features of transistor devices may be well-known to those skilled in the art of transistor circuit design and, in order to avoid prolixity, those features will not be separately identified here.

Signal receiving unit 112 may receive an input signal IN at the gate of NMOS transistor device 130 and at an input node of inverter device 134. Inverter device 134 may receive a first reference signal V_{CC1}. Inverter device 134 may be coupled to provide an inverted input signal I̅N̅ to the gate of NMOS transistor device 132. Input signal IN preferably may vary between a first low logic level 0 and a first high logic level V_{CC1}. Signal receiving unit 112 may present a first signal (Indicated as signal V₁ in FIG. 1; not indicated in FIG. 3) at the drains of PMOS transistor devices 140, 142 of signal treating section 120. First signal V₁ may vary between first low logic level 0 and a first high logic level V_{CC1}.

The gate of PMOS transistor device 140 may be coupled with the drain of PMOS transistor device 142. The gate of PMOS transistor device 142 may be coupled with the drain of PMOS transistor device 140. Signal treating section 120 may receive first signal V₁ at the drains of PMOS transistor devices 140, 142 and may present a second signal V₂ at the drains of PMOS transistor devices 140, 142 when PMOS transistor devices may be gated on in a conducting state. Second signal V₂ may vary between a second low logic level 0 and a second high logic level V_{CC2}.

Isolating section 122 may receive a control signal EN at the gates of NMOS transistor devices 150, 152. Isolating section 122 may respond to control signal EN to permit presenting second signal V₂ when control signal EN is in a low state (that is, at too low a level to gate NMOS transistor devices 150, 152). Isolating section 122 may respond to control signal EN to not permit presenting second signal V₂ when control signal EN is in a sufficiently high state to gate NMOS transistor devices 150, 152. Gating NMOS transistor devices 150, 152 may effect coupling of drains of PMOS transistors 140, 142 to ground whenever NMOS transistor devices 130, 132 are conducting.

Output unit 116 may also receive control signal EN. Output unit 116 may permit presentation of an output signal OUT when control signal EN may have a low value and NMOS transistor devices may not be conducting. Output signal OUT may be related with second signal V₂. Output unit 116 may establish output signal OUT at a predetermined value when control signal EN may have a sufficiently high value to gate NMOS transistor devices 150, 152.

It may be preferred that apparatus 110 is embodied in a single integrated circuit.

FIG. 4 illustrates a first embodiment of an apparatus effecting interface between differing signal levels employing PMOS isolation. In FIG. 4, an apparatus 210 may be an implementation of apparatus 10 (FIG. 1) including a signal receiving unit 212, a signal treating section 220, an isolating section 222 and an output unit 216.

Signal receiving unit 212 and signal treating section 220 may be substantially similar in construction and operation to signal receiving unit 112 and signal treating section 120 (FIG. 3). In order to avoid prolixity signal receiving unit 212 and signal treating unit 220 will not be further described here.

Isolating section 222 may receive a control signal EN at an inverter device 251 to present an inverted control signal E̅N̅ at the gates of PMOS transistor devices 250, 252. Isolating section 222 may respond to control signal EN to permit presenting second signal V₂ when control signal EN may be in a high state (that is, at a sufficiently high level to permit inverted control signal E̅N̅ to gate PMOS transistor devices 250, 252). Isolating section 222 may respond to control signal EN to not permit presenting second signal V₂ when control signal EN may be in too low a state to permit inverted control signal E̅N̅ to gate PMOS transistor devices 250, 252. Gating PMOS transistor devices 250, 252 may effect coupling of drains of PMOS transistors 140, 142 to reference voltage V_{CC2}, thereby permitting signal level shifting by signal treating unit 220 to a signal level appropriate for use by output unit 216 in presenting output signal OUT, as described earlier herein in connection with FIG. 3.

It may be preferred that apparatus 210 is embodied in a single integrated circuit.

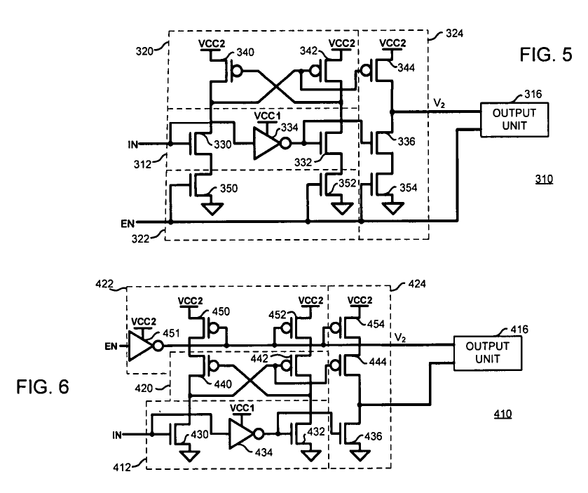

FIG. 5 illustrates a second embodiment of an apparatus effecting interface between differing signal levels employing NMOS isolation. In FIG. 5, an apparatus 310 may be an implementation of apparatus 11 (FIG. 2) including a signal receiving unit 312, a signal treating section 320, an isolating section 322, an output unit 116 and an output section 324.

Signal receiving unit 312, signal treating section 320 and isolating section 322 may be substantially similar in construction and operation to signal receiving unit 112, signal treating section 120 and isolating section 122 (FIG. 3). In order to avoid prolixity signal receiving unit 312, signal treating section 320 and isolating section 322 will not be further described here.

Output section 324 may control output of signals to output unit 316 in response to control signal EN. Output section 324 may receive control signal EN at the gate of NMOS transistor device 354. Output section 324 may respond to control signal EN to permit presenting second signal V₂ when control signal EN may be in a low state (that is, at too low a level to gate NMOS transistor device 354). Output section 324 may respond to control signal EN to not permit presenting second signal V₂ when control signal EN may be in a sufficiently high state to gate NMOS transistor device 345. Gating NMOS transistor device 354 may effect coupling of drain of PMOS transistor 344 to ground whenever NMOS transistor device 336 may be conducting.

Providing a separate output section 324 in apparatus 310 may permit a designer to employ a variety of component sizes and capacities in order to effect a balanced operation of apparatus 310. By way of example and not by way of limitation, providing output section 324 may permit improved gain for higher power levels with larger loads and better delay characteristics as compared with an apparatus without a separate output section.

It may be preferred that apparatus 310 is embodied in a single integrated circuit.

FIG. 6 illustrates a second embodiment of an apparatus effecting interface between differing signal levels employing PMOS isolation. In FIG. 6, an apparatus 410 may be an implementation of apparatus 11 (FIG. 2) including a signal receiving unit 412, a signal treating section 420, an isolating section 422, an output unit 116 and an output section 424.

Signal receiving unit 412, signal treating section 420 and isolating section 422 may be substantially similar in construction and operation to signal receiving unit 212, signal treating section 220 and isolating section 222 (FIG. 4). In order to avoid prolixity signal receiving unit 412, signal treating section 420 and isolating section 422 will not be further described here.

Output section 424 may control output of signals to output unit 416 in response to control signal EN. Output section 424 may receive control signal EN at an inverter device 451 to present an inverted control signal E̅N̅ at the gate of PMOS transistor device 454. Output section 424 may respond to inverted control signal E̅N̅ at the gate of PMOS transistor device 454 to permit presenting second signal V₂ when control signal EN may be in a high state (that is, at a sufficiently high level to permit inverted control signal E̅N̅ to gate PMOS transistor device 454. When PMOS transistor device 454 is gated, reference signal V_{CC2} may be presented to output unit 416. Output section 424 may respond to inverted control signal E̅N̅ at the gate of PMOS transistor device 454 to not permit presenting second signal V₂ when control signal EN may be in a low state (that is, at a sufficiently low level to prevent inverted control signal E̅N̅ from gating PMOS transistor device 454.

It may be preferred that apparatus 410 is embodied in a single integrated circuit.

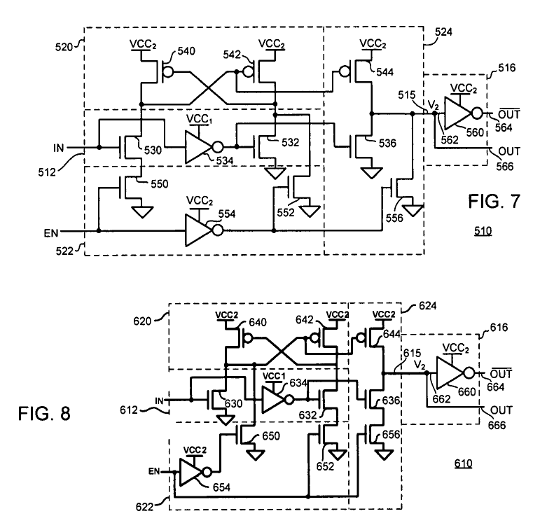

FIG. 7 illustrates a first embodiment of an apparatus effecting interface between differing signal levels employing logic level isolation. In FIG. 7, an apparatus 510 may include a signal receiving unit 512, a signal treating section 520, an isolating section 522, an output section 524 and an output unit 516.

Signal receiving unit 512 and signal treating section 520 may be substantially similar in construction and operation to signal receiving unit 312 and signal treating section 320 (FIG. 5). In order to avoid prolixity signal receiving unit 512 and signal treating section 520 will not be further described here.

Isolating section 522 may differ from earlier described isolating sections, such as isolating section 322 (FIG. 5) at least in that isolating section 520 may respond to control signal EN to directly affect signal treating section 520 by setting one of the gate-to-drain cross couplings between PMOS transistor devices 540, 542 to effect a turning on or off of the level setting function of apparatus 510. An inverter device 554 may ensure that only one of the cross-couplings is affected at a time. That is, signal treating section 520 may be effectively disabled when control signal EN may be low so that NMOS transistor 550 may not be conducting and NMOS transistor 552 may be conducting. PMOS transistor device is thereby gated on and level shifting of input signal IN may be carried out to provide a shifted output signal at output locus 515. When control signal EN is high, NMOS transistor device may be gated on and coupling of drain of PMOS transistor 540 to ground may occur whenever NMOS transistor device 530 is conducting. Also, NMOS transistor device may be off, so that signal V₂ at output locus 515 may be established at level V_{CC2}. Apparatus 510 may be recognized as operating as a drive-high output device when control signal EN is high.

Inverter device 554 also may invert control signal EN to present inverse control signal E̅N̅ to the gate of NMOS transistor device 556. Output section 524 may respond to a high control signal EN presenting a low inverted control signal E̅N̅ at the gate of NMOS transistor 556 to permit presenting second signal V₂ at output locus 515. Output section 524 may respond to a low control signal EN presenting a high inverted control signal E̅N̅ at the gate of NMOS transistor 556 to gate NMOS transistor device 556 on. Gating NMOS transistor device 556 on may couple ground potential to output locus 515 so that output section 524 may not permit presenting second signal V₂ at output locus 515.

Apparatus 510 may include an output unit 516. Output unit 516 may include an inverter device 560 receiving signal V2 at an input locus 562. Output unit 516 may present an output signal OUT from input locus 562 and may present an inverted output signal O̅U̅T̅ at an output locus 566.

It may be preferred that apparatus 510 is embodied in a single integrated circuit.

FIG. 8 illustrates a second embodiment of an apparatus effecting interface between differing signal levels employing logic level isolation. In FIG. 8, an apparatus 610 may include a signal receiving unit 612, a signal treating section 620, an isolating section 622, an output section 624 and an output unit 616.

Signal receiving unit 612, signal treating section 620 and output section 624 may be substantially similar in construction and operation to signal receiving unit 312, signal treating section 320 and output section 324 (FIG. 5). Output unit 616 may be substantially similar in construction and operation to output unit 516 (FIG. 7). In order to avoid prolixity signal receiving unit 612, signal treating section 620, output section 624 and output unit 616 will not be further described here.

Isolating section 622 differs from earlier described isolating sections, such as isolating section 122 (FIG. 3) at least in that isolating section 620 may respond to control signal EN to directly affect signal treating section 620 by setting one of the gate-to-drain cross couplings between PMOS transistor devices 640, 642 to effect a turning on or off of the level setting function of apparatus 610. An inverter device 654 may ensure that only one of the cross-couplings is affected at a time. That is, signal treating section 620 may be effectively disabled when control signal EN may be low and NMOS transistor 650 may be conducting.

It may be preferred that apparatus 610 is embodied in a single integrated circuit.

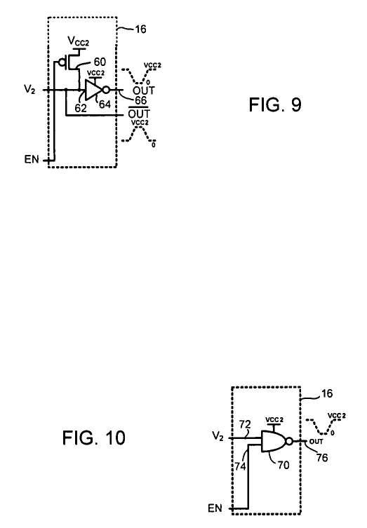

FIG. 9 illustrates a first embodiment of an output unit appropriate for use with an apparatus effecting interface between differing signal levels. In FIG. 9, an output unit 16 may be configured as a drive-low driver unit. Output unit 16 may include a PMOS transistor device 60 coupled with an input locus 62 of an inverter device 64 and with a reference signal V_{CC2}. An output signal OUT may be presented at an output locus 66 of inverter device 64. An inverted output signal O̅U̅T̅ may be presented at input locus 62. When control signal EN may be sufficiently low to gate PMOS transistor device 60, signal OUT may be driven to 0 and signal O̅U̅T̅ may be driven to V_{CC2}. When control signal EN may not be sufficiently low to gate PMOS transistor device 60, signal OUT may be driven to V_{CC2} and signal O̅U̅T̅ may be driven to 0.

FIG. 10 illustrates a second embodiment of an output unit appropriate for use with an apparatus effecting interface between differing signal levels. In FIG. 10, an output unit 16 may be configured as a drive-high driver unit. Output unit 16 may include a NAND gate 70 having with a first input locus 72 coupled to receive output signal V₂, and having a second input locus 74 coupled for receiving control signal EN. NAND gate 70 also may have an output locus 76 at which may be presented an output signal OUT. NAND gate 70 may present output signal OUT at a value V_{CC2} whenever both of signals V₂, EN may be high. Whenever either of signals V₂, EN may be low, output signal OUT may be at 0.

While certain features of embodiments of the invention have been illustrated and described herein, many modifications, substitutions, changes, and equivalents will now occur to those skilled in the art. It is, therefore, to be understood that the appended claims are intended to cover all such modifications and changes as fall within the true spirit of embodiments of the invention.

1. An apparatus comprising:
(a) a signal receiving unit to receive an input signal and present a first signal related with said input signal; said first signal varying within a first signal range; and
(b) a signal treating unit coupled with said signal receiving unit to receive said first signal and present a second signal related with said first signal; said second signal varying within a second signal range;
said signal treating unit receiving a control signal; said signal treating unit responding to said control signal to provide said second signal at an output locus when said control signal has a first value; said signal treating unit responding to said control signal to not provide said second signal at said output locus when said control signal has a second value.

2. An apparatus as recited in claim 1 wherein said signal receiving unit and said signal treating unit are embodied in a single integrated circuit.

3. An apparatus as recited in claim 1 wherein said signal treating unit includes an integral isolation unit to receive said control signal; said isolation unit responding to said control signal for controlling said providing said second signal.

4. An apparatus as recited in claim 1 wherein said signal treating unit includes an output unit to receive said control signal; said output unit permitting presentation of an output signal when said control signal has said first value; said output signal being related with said second signal; said output unit establishing said output signal at a predetermined value when said control signal has said second value.

5. An apparatus as recited in claim 4 wherein said signal receiving unit, said signal treating unit and said output unit are embodied in a single integrated circuit.

6. An apparatus as recited in claim 2 wherein said signal treating unit includes an integral isolation unit to receive said control signal; said isolation unit responding to said control signal for controlling said providing said second signal.

7. An apparatus as recited in claim 6 wherein said signal receiving unit, said signal treating unit and said output unit are embodied in a single integrated circuit.

8. An apparatus as recited in claim 3 wherein said signal treating unit includes an output unit to receive said control signal; said output unit permitting presentation of an output signal when said control signal has said first value; said output signal being related with said second signal; said output unit establishing said output signal at a predetermined value when said control signal has said second value.

9. An apparatus as recited in claim 4 wherein said signal treating unit employs NMOS transistor devices to configure said signal treating unit for not providing said second signal to said output unit when said control signal is high enough to effect gating said NMOS transistor devices.

10. An apparatus as recited in claim 4 wherein said signal treating unit employs PMOS transistor devices to configure said signal treating unit for not providing said second signal to said output unit when said control signal is low enough to effect gating said PMOS transistor devices.

11. An apparatus as recited in claim 9 wherein said output unit establishes said output signal at a high logic level when said control signal is high enough to effect gating said NMOS transistor devices.

12. An apparatus as recited in claim 10 wherein said output unit establishes said output signal at a high logic level when said control signal is low enough to effect gating said PMOS transistor devices.

13. An apparatus as recited in claim 9 wherein said output unit establishes said output signal at a low logic level when said control signal is high enough to effect gating said NMOS transistor devices.

14. An apparatus as recited in claim 10 wherein said output unit establishes said output signal at a low logic level when said control signal is low enough to effect gating said PMOS transistor devices.

15. An apparatus comprising:
(a) a signal receiving unit to receive an input signal and present a first signal related with said input signal; said first signal varying between a first low logic signal level and a first high logic signal level; and
(b) a signal treating unit coupled with said signal receiving unit to receive said first signal and present a second signal related with said first signal; said second signal varying between a second low logic signal level and a second high logic signal level; and
said signal treating unit receiving a control signal; said signal treating unit responding to said control signal to provide said second signal at an output locus when said control signal has a first value; said signal treating unit responding to said control signal to not provide said second signal to said output locus when said control signal has a second value;
said signal treating unit including an output unit; said output unit permitting presentation of an output signal when said control signal has said first value; said output signal being related with said second signal; said output unit establishing said output signal at a predetermined value when said control signal has said second value.

16. An apparatus as recited in claim 15 wherein said signal receiving unit and said signal treating unit are embodied in a single integrated circuit.

17. An apparatus as recited in claim 16 wherein said signal treating unit includes an integral isolation unit to receive said control signal; said isolation unit responding to said control signal for controlling said providing said second signal.
